(19) United States
(12) Patent Application Publication
(10) Pub. No.: US 2009/0085172 A1
(43) Pub. Date: Apr. 2, 2009

(54) Deposition Method, Deposition Apparatus, Computer Readable Medium, and Semiconductor Device

(75) Inventors: Masahiro Horigome, Nirasaki-Shi (JP); Shigekazu Hirose, Nirasaki-Shi (JP)

Correspondence Address: IPUSA, P.L.L.C, 1054 31ST STREET, N.W., Suite 400, Washington, DC, 20007, US

(73) Assignee: TOKYO ELECTRON LIMITED

(21) Appl. No.: 12/238,692

(22) Filed: Sep. 26, 2008

(30) Foreign Application Priority Data
Sep. 28, 2007 (JP) 2007-256330

(51) Int. Cl. H01L 21/4763; C23C 14/32; H01L 23/58; G06F 19/00

(52) U.S. Cl. 257/632; 438/622; 118/723 VE; 700/121; 257/E21.241

(57) ABSTRACT

A deposition method includes steps of placing a substrate on a susceptor in a process chamber; supplying to the process chamber a source gas including an organic compound and a plasma gas for facilitating activation of the source gas into plasma; evacuating the process chamber to a reduced pressure; generating plasma of the plasma gas and the source gas in the process chamber to deposit a barrier film including carbon on the substrate; and applying high frequency bias electric power to the susceptor during the plasma generating step.

### BACKGROUND OF THE INVENTION

1. Field of the Invention

The present invention relates to a deposition technology of plasma depositing a barrier film interposed between an interconnect metal and an inter-layer insulating film in a semiconductor device.

2. Description of the Related Art

A multilayer interconnect structure for achieving higher integration in a semiconductor device is built up by simultaneously forming trenches to be filled in order to form a metal liner and via holes to be filled in order to connect a lower level metal line with an upper level metal line in a lower level interlayer insulating film; filling the trenches and the via holes with an interconnect metal, for example, copper, thereby forming the lower level structure; and stacking such structures one on another, for example, when a dual damascene process is employed. In such a structure, it is necessary to prevent or impede diffusion of the metal into the interlayer insulating film. Especially, when copper is used as the interconnect metal, because copper is relatively highly diffusive, barrier metal needs to be applied on inner walls of concave portions including the trenches and the via holes, and a barrier film is formed between a copper line in the trenches and an upper level interlayer insulating film in order to prevent or impede the copper diffusion.

FIG. 1 schematically illustrates a part of a structure where a copper line 112 is formed in a trench in a lower level interlayer insulating film 111, and electrodes 113 are formed on the copper line 112. In this drawing, 114 denotes barrier metal deposited on inner walls of concave portions of the trench and a via hole (not shown); and 115 denotes a barrier film interposed between the copper line 112 and an upper level interlayer insulating film (not shown). The barrier metal 114 is formed before the copper line 112 is formed, and thus the barrier metal 114 remains between the lower surface of the copper line 112 (plug) and the upper surface of another copper line below the copper line 112. Therefore, the barrier metal 114 needs to be electrically conductive and thus formed of a film including, for example, tantalum, titanium, and the like.

On the other hand, because the barrier film 115 is formed to blanket the copper line 112 except for areas where the electrodes 113 contact the copper line 112, the barrier film 115 exists mainly between the lower level interlayer insulating film and the upper level interlayer insulating film (not shown) in order to impede copper diffusion into the upper level interlayer insulating film. In order to avoid an increase in a dielectric constant of the interlayer insulating film, which may be caused by copper diffusion into the insulating film, the barrier film 115 is formed of, for example, SiCN by, for example, plasma CVD using trimethylsilane gas and nitrogen gas (Patent Document 1). Alternatively, the barrier film 115 is formed of SiC, amorphous carbon, and the like.

While the barrier films 115 are expected to be made thinner along with miniaturization of semiconductor devices, if the barrier film 115 becomes too thin, copper atoms diffuse through the barrier film 115 into the upper level interlayer insulating film, which deteriorates insulation of the interlayer insulating film and thus increases leakage current flowing through interlayer insulation film. Therefore, a highly dense barrier film is expected to be used in order to realize a high barrier capability even in the case of further miniaturization.

Furthermore, use of a fluoridated carbon film (fluorocarbon film), which is a compound of carbon (C) and fluorine (F), as the interlayer insulating film is under consideration because such a film can provide a relative dielectric constant as low as 2.5 or below. However, because fluorine atoms are likely to disgregate when the fluoridated carbon film is heated, fluorine atoms can diffuse through the barrier film 115 from the upper level interlayer insulating film, which overlies the barrier film 115, into the copper line 112, which may increase resistivity of the copper line 112.

Patent Document 2 describes an experiment where the fluoridated carbon film is formed by applying bias electric power of 500 W or more to an 8-inch wafer in a plasma apparatus employing electron cyclone resonance. However, Patent Document 2 does not mention the above problems.

Patent Document 1: Japanese Patent Application Laid-Open Publication No. 2006-294816.

Patent Document 2: Japanese Patent Application Laid-Open Publication No. H10-144675, FIG. 19, paragraph 0046.

### SUMMARY OF THE INVENTION

The present invention has been made in view of the above and is directed to a deposition method, a deposition apparatus, and a computer readable medium storing a program for executing the deposition method, which are able to provide a barrier film with high barrier capability interposed between an interconnect metal and an interlayer insulating film in a semiconductor device. In addition, the present invention is directed to a semiconductor device with the barrier film with high barrier capability.

A first aspect of the present invention provides a deposition method of depositing a barrier film to be interposed between an interconnect metal and an interlayer insulating film. The method includes steps of placing a substrate on a susceptor in a process chamber; supplying to the process chamber a source gas including an organic compound and a plasma gas for facilitating activation of the source gas into plasma; evacuating the process chamber to a reduced pressure; generating plasma of the plasma gas and the source gas in the process chamber to deposit the barrier film including carbon on the substrate; and applying high frequency bias electric power to the susceptor during the plasma generating step.

A second aspect of the present invention provides a deposition method according to the first aspect, wherein the plasma gas and the source gas are supplied to the process chamber from different supplying ports and activated into plasma by supplying microwaves to the process chamber through a planar antenna member including plural slots formed along a circumferential direction, the planar antenna member being arranged in an upper portion of the process chamber in order to face the susceptor.

A third aspect of the present invention provides a deposition method according to the second aspect, wherein the high frequency bias electric power per unit area of the substrate is 0.047 watts/cm² or less.

A fourth aspect of the present invention provides a deposition method according to any one of the first through the third aspects, wherein the source gas includes a silicon organic compound, and wherein the barrier film includes silicon.

A fifth aspect of the present invention provides a deposition method of the fourth aspect, wherein the barrier film is a SiCN film.

A sixth aspect of the present invention provides a deposition method of the fourth aspect, wherein the barrier film is a SiC film.

A seventh aspect of the present invention provides a deposition method according to any one of the first through the third aspects, wherein the barrier film is an amorphous carbon film.

An eighth aspect of the present invention provides a deposition method of the seventh aspect, wherein the source gas is butyne gas.

A ninth aspect of the present invention provides a deposition method of the eighth aspect, wherein the source gas includes a silane series gas in addition to the butyne gas, and wherein the amorphous carbon film includes silicon.

A tenth aspect of the present invention provides a deposition method according to any one of the first through the ninth aspects, wherein the plasma gas is argon gas.

An eleventh aspect of the present invention provides a deposition method according to any one of the first through the tenth aspects, wherein the interlayer insulating film is a fluorine-added carbon film.

A twelfth aspect of the present invention provides a deposition apparatus by which a barrier film to be interposed between an interconnect metal and an interlayer insulating film is deposited. The apparatus includes a process chamber including a susceptor on which a substrate is placed; a gas supplying portion that supplies to the process chamber a source gas including an organic compound and a plasma gas for facilitating activation of the source gas into plasma; an evacuation unit that evacuates the process chamber to a reduced pressure; a plasma generation portion that activates gas in the process chamber into plasma; an applying unit that applies high frequency bias electric power to the susceptor; and a control unit that controls the gas supplying chamber, the gas supplying portion, the evacuation unit, the plasma generation portion and the applying unit so that the plasma gas and the source gas including the organic compound are supplied to the process chamber and activated into plasma and the barrier film including carbon is deposited with the high frequency bias electric power applied to the susceptor.

A thirteenth aspect of the present invention provides a deposition apparatus of the twelfth aspect, wherein the gas supplying portion includes a supplying port through which a plasma gas to be excited by microwaves is supplied to the process chamber and another supplying port through which the source gas is supplied to the process chamber; and wherein the plasma generation portion includes a waveguide that guides the microwaves to an upper portion of the process chamber, and a planar antenna member that is connected to the waveguide in order to guide the microwaves from the waveguide to the process chamber and arranged to face the susceptor, the planar antenna member including plural slots formed along a circumferential direction.

A fourteenth aspect of the present invention provides a deposition apparatus of the thirteenth aspect, wherein the high frequency bias electric power per unit area of the substrate is 0.047 watts/cm² or less.

A fifteenth aspect of the present invention provides a computer readable medium including a computer program stored therein, wherein the computer program is executed on a computer in a deposition apparatus, and wherein steps of performing the deposition method of the first aspect are incorporated in the computer program.

A sixteenth aspect of the present invention provides a semiconductor device comprising a barrier film deposited by the deposition method of the first aspect.

According to an embodiment of the present invention, the high frequency bias electric power is applied to the susceptor on which the substrate is placed when the source gas including the organic compound and the plasma gas for facilitating activation of the source gas into plasma are supplied to the process chamber, and activated into plasma, thereby depositing on the substrate the barrier film to be interposed between the interconnect metal and the interlayer insulating film, the barrier film including carbon. Because of the bias electric power, active species such as ions of the plasma gas, for example, argon ions impinge upon the substrate when the barrier film is being deposited. Therefore, the impinging species may make the barrier film dense and provide the barrier film with higher barrier capability.

### BRIEF DESCRIPTION OF THE DRAWINGS

Other features and advantages of the present invention will become more apparent from the following detailed description when read in conjunction with the accompanying drawings:

FIG. 1 illustrates part of a related art multilayer interconnection structure;

FIGS. 2A through 2D are step-by-step representations of a cross section of a semiconductor device under fabrication, the device including a fluoridated carbon (CF) film;

FIGS. 3A through 3C are subsequent step-by-step representations of a cross section of a semiconductor device under fabrication, the device including a fluoridated carbon film;

FIGS. 4A and 4B are explanatory views of a presumed deposition mechanism when a SiCN film is deposited by a deposition method according to an embodiment of the present invention;

FIG. 5 is a schematic view of a deposition apparatus according to an embodiment of the present invention;

FIG. 6 is a plan view of a second gas supplying portion used in the deposition apparatus of FIG. 5;

FIG. 7 is a partial cross-sectional perspective view of the second gas supplying portion of FIG. 6;

FIGS. 8A and 8B show experimental results of an amount of HF and F outgassing from the CF film in relation to temperature;

FIG. 9A shows a depth profile of fluorine atoms diffusing into the SiCN film from the CF film;

FIG. 9B shows a depth profile of oxygen atoms incorporated into the SiCN film and the CF film;

FIG. 10 shows experimental results of a deposition rate and a refractive index in relation to bias power applied to a wafer during deposition of the SiCN film;

FIG. 11 summarizes experimental results of appearance observation and adhesion testing;

FIG. 12 schematically illustrates a four point bending method employed to evaluate adhesive strength of the SiCN film onto the CF film;

FIGS. 13A and 13B show experimental data obtained by the four point bending method;

FIG. 14 summarizes an experimental result of the four point bending method in relation to the bias power;

FIG. 15 summarizes another experimental result of the four point bending method in relation to the bias power and plasma exposure time;

FIG. 16 summarizes yet another experimental result of the four point bending method in relation to the bias power and plasma exposure time; and

FIG. 17 summarizes other experimental results of appearance observation and adhesion testing.

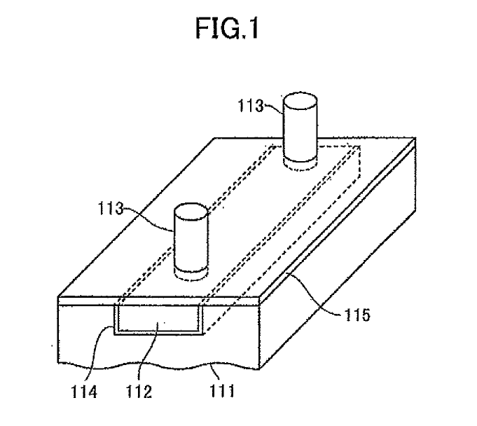

### DETAILED DESCRIPTION OF THE PREFERRED EMBODIMENT

Non-limiting, exemplary embodiments of the present invention are described with reference to the accompanying drawings. In the drawings, the same or corresponding reference symbols are given to the same or corresponding members or components. It is to be noted that the drawings are illustrative of the invention, and there is no intention to indicate scale or relative proportions among the members or components, or between thicknesses of various layers, alone or therebetween. Therefore, the specific thickness or size should be determined by a person having ordinary skill in the art in view of the following non-limiting embodiments.

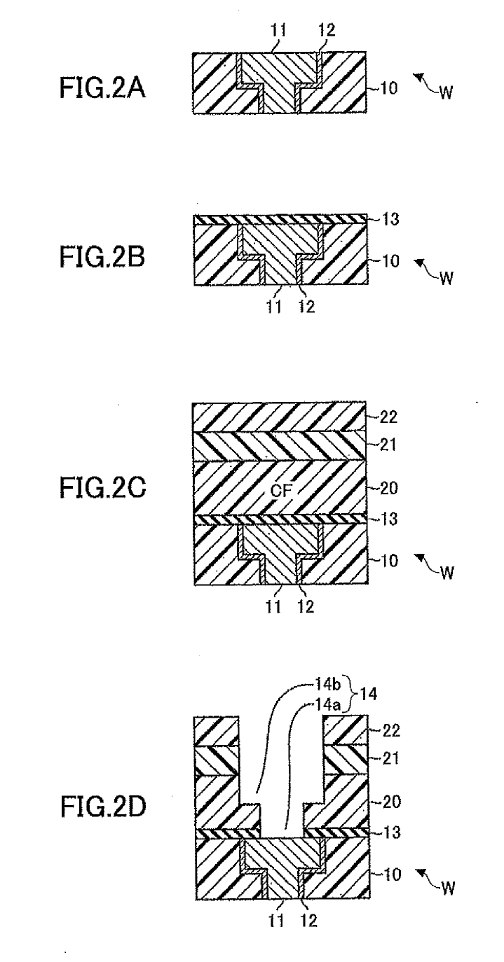

Referring to FIG. 2, a semiconductor device fabrication method carried out employing a deposition method according to preferable embodiments of the present invention is described. FIG. 2A shows an n-th circuit layer formed in a wafer W, which has, for example, a diameter of 200 mm (8 inches). In the circuit layer, an interconnect metal 11 of, for example, copper is embedded in a fluoridated carbon film 10 (referred to as a CF film 10 below), which is an interlayer insulating film. Between the CF film 10 and the interconnect metal 11, a barrier metal film 12 is interposed in order to impede diffusion of copper atoms of the interconnect metal 11 into the CF film 10. The barrier metal film 12 may be formed of tantalum, tantalum nitride, and the like. By the way, the n-th circuit layer may be referred to as a lower layer and an (n+1)-th circuit layer may be referred to as an upper layer, hereinafter.

As shown an FIG. 2B, a barrier film 13 is deposited on an upper surface of the lower layer in order to impede the diffusion of the metal and outgas constituents that may take place between the lower layer and the upper layer. The barrier film 13 may be formed of an insulating compound, for example, SiCN. The barrier film 13 formed of SiCN can be deposited by supplying source gases such as trimethylsilane ((CH₃)₃SiH), which is an organic silicon compound, and nitrogen (N₂) and a plasma gas such as argon (Ar) to the wafer W heated at, for example, 350° C. and exciting the argon gas and the source gases using microwave energy to generate argon plasma in a plasma deposition apparatus described below. In this case, the argon gas is used to generate plasma that facilitates generating plasma of the source gases. Instead of the argon gas, other noble gases, for example, Kr and the like may be used. In addition, NH₃, N₂O, and the like may be used instead of N₂ gas.

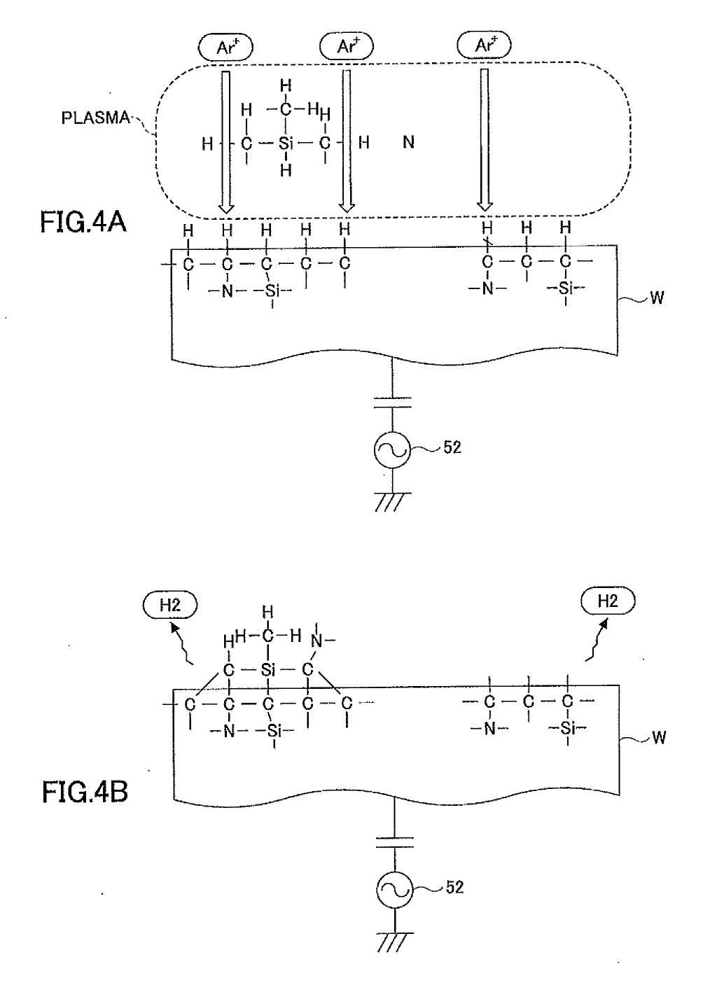

When the barrier film 13 is deposited, high frequency electric power of, for example, about 10 watts is applied to the wafer W from a high frequency electric power source 52 (described below) for biasing. The frequency of the high frequency electric power may be in a range of, for example, 2 MHz or below, which ions in the plasma can follow, or preferably 800 kHz. The argon ions in the plasma are drawn to the wafer W by the high frequency electric power having such frequencies. Because of the application of the high frequency electric power, a barrier capability of the barrier film 13 can be enhanced, which may be achieved through densification of the barrier film 13, as explained in reference to FIGS. 4A and 4B. When the trimethylsilane gas is activated, various active species are produced that include a trimethylsilane molecule where part of C—H bonds are broken or a trimethylsilane molecule where Si—C or Si—H bonds are broken.

As shown in FIG. 4A, the argon ions are drawn to the wafer W and collide against such active species existing near the surface of the wafer W on the way, which breaks a relatively weak bond such as a C—H bond in the active species and expels the hydrogen atom. Then, the carbon atom that has lost the hydrogen atom may be bonded with another carbon atom of another active specie, or another carbon atom that exists on the surface of the barrier film 13 and terminates a dangling bond.

On the other hand, the hydrogen atoms that are expelled from the active species can be bonded with each other into a hydrogen molecule and exhausted from the process environment without being incorporated into the barrier film 13. Because such a chemical process takes place on and near the upper surface of the wafer W, C—C bond networks are formed and those bonds grow into cross-links in the barrier film 13. In such a manner, the barrier film 13 is thought to become dense and hard.

Alternatively, when the argon ions collide against the upper surface of the wafer W (the barrier film 13), a C—H bond, which is also relatively weak, is broken on the upper surface of the wafer W (FIG. 4A), and the dangling bond is formed (FIG. 4B). Because a portion where the dangling bond is formed is chemically active, a sticking coefficient of the active species is increased, thereby increasing a deposition rate of the barrier film 13. As stated, the barrier film 13 becomes dense and hard and the deposition rate is increased by applying the high frequency bias to the wafer W compared to when no such bias is applied.

Referring to FIG. 2C, a CF film 20 is deposited on the upper surface of the barrier film 13. The CF film 20 serves as the interlayer insulating film. The CF film 20 is deposited by supplying plasma including active species of C₅F₈ gas, which are produced by plasma exciting the C₅F₈ gas as a source gas including carbon and fluorine and the argon gas, to the wafer W. In this case, the wafer is heated at, for example, 380° C.; a flow rate of the source gas is, for example, 200 sccm; a flow rate of the argon gas is, for example, 300 sccm; and pressure inside a chamber is, for example, about 7.33 Pa (about 55 mTorr).

It should be noted that the source gas such as a gas composed of carbon and fluorine does not contain the hydrogen atoms and the plasma does not include the hydrogen (atoms, radicals, ions and the like). When the CF film 20 is deposited under an environment including hydrogen, the hydrogen atoms or the like may be incorporated into the CF film 20 and the hydrogen atoms react with fluorine in the CF film 20 to produce HF gas, which leaves the CF film 20 to reach another barrier film that overlies the CF film 20. As a result, the barrier film may become less adhesive and the CF film 13 may lose hardness.

Next, a SiCN film 21 and a SiCOH film 22 that serve as sacrifice layers are stacked in this order on the CF film 20 (FIG. 2C). Then, a resist mask (not shown) is formed on the SiCOH film 22. The resist mask and the sacrifice layers are used to etch the CF film 20 using plasma including active species of halide, thereby forming a concave portion 14 composed of a concave portion 14a corresponding to a via hole and a concave portion 14b corresponding to a buried interconnection (trenches) of an overlying circuit (FIG. 2D).

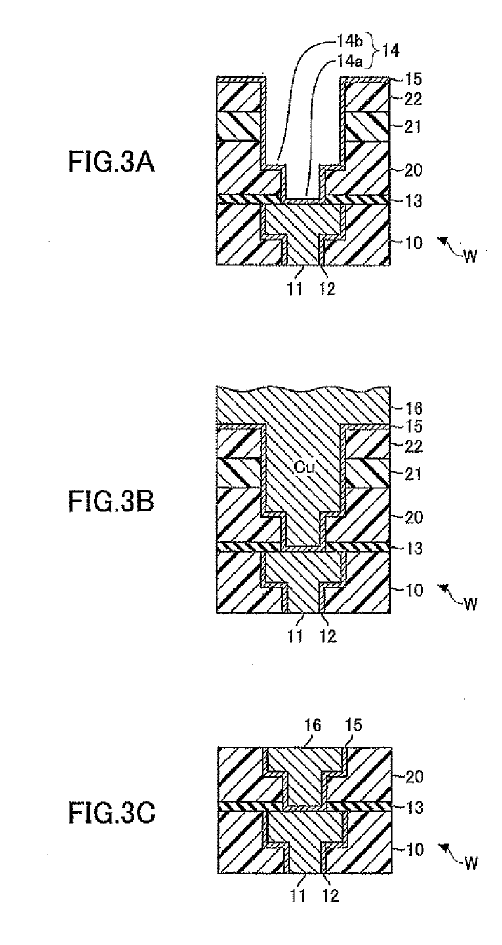

Next, an electrically conductive barrier metal film 15 such as a tantalum film, a tantalum nitride film and the like is deposited on an inner surface of the concave portion 14 (FIG. 3A). After an interconnect metal 16 of, for example, copper is buried in the concave portion 14 (FIG. 3B), redundant portions of the interconnect metal 16, the SiCOH film 22, and SiCN film 21 are removed by Chemical Mechanical Polishing (CMP), and thus the upper circuit layer is formed (FIG. 3C). After this, the same procedures are repeated predetermined times so that a semiconductor device is fabricated. Furthermore, after the multilayer structure of the circuit layers is formed, an annealing process may be carried out for the structure at an annealing temperature of, for example, 400° C. in order to reduce the number of the dangling bonds in each film.

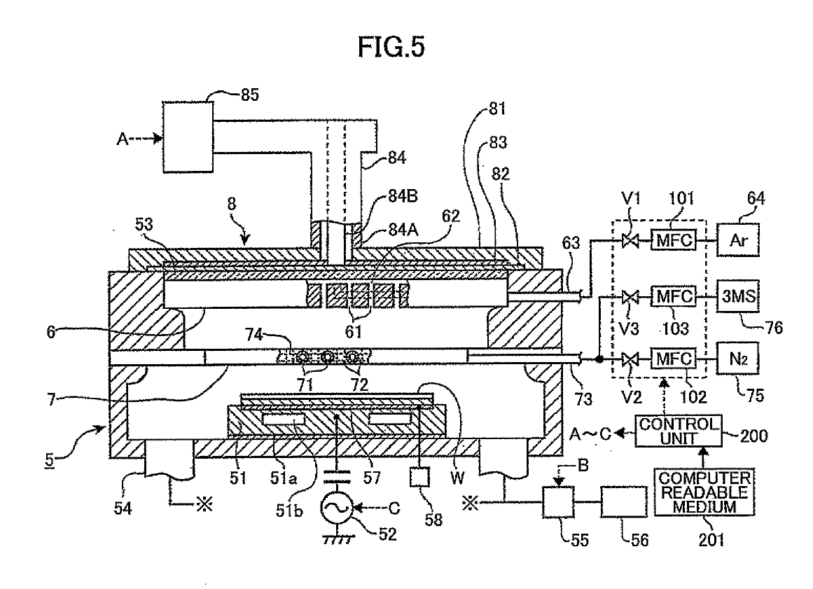

Next, a deposition apparatus according to an embodiment of the present invention and a specific example of a deposition method carried out using the deposition apparatus are described in reference to FIGS. 5 through 7. The deposition apparatus is configured as a Plasma enhanced Chemical Vapor Deposition apparatus employing a Radial Line Slot Antenna for generating plasma. In FIG. 5, 5 denotes a process container (vacuum chamber) configured to be cylindrical as a whole. A side wall and a bottom portion of the chamber 5 are made of an electrically conductive material such as aluminum-added stainless steel and the like, and a protection film of, for example, aluminum oxide is formed on an inner wall of the chamber 5.

In a substantially centeral portion of the chamber 5, a susceptor 51 on which a substrate (e.g., a water W) is placed is provided via an insulating member 51a. The susceptor 51 is made of, for example, aluminum nitride (AlN) or aluminum oxide (Al₂O₃) and includes a cooling jacket 51b that allows a cooling medium to flow therethrough. In addition, the susceptor 51 includes a heater 57 that is connected to a power source 58. A wafer receiving surface of the susceptor 51 is configured as an electrostatic chuck. Moreover, the susceptor 51 is connected to a high frequency electric power source 52 for biasing that supplies high frequency electric power having a frequency of 2 MHz or below, preferably favorably 800 kHz, which ions can follow, to the susceptor 51.

The chamber 5 has an opening at the upper portion and a first gas-supplying portion 6 having a substantially circular top view shape is provided in the opening via a sealing member such as an O-ring (not shown). The first gas supplying portion 6 faces the susceptor 51 and is made of, for example, aluminum oxide. In addition, the first gas-supplying portion includes a gas passage 62 that is in communication with one end portion of gas supplying orifices 61 that are open toward the susceptor 51. The gas passage 62 is connected to one end portion of a first gas-supplying conduit 63. The other end portion of the first gas-supplying conduit 63 is connected to a gas supplier 64 of the plasma gas such as argon (Ar) gas, krypton (Kr) gas and the like. The plasma gas is supplied to the gas passage 62 through the first gas-supplying conduit 63 and thus uniformly toward a space below the first gas-supplying portion 6 through the gas-supplying orifices 61.

In the illustrated example, the gas supplier 64, the first gas-supplying conduit 63, and the first gas-supplying portion 6 constitute a plasma gas supplier that supplies the plasma gas into the chamber 5.

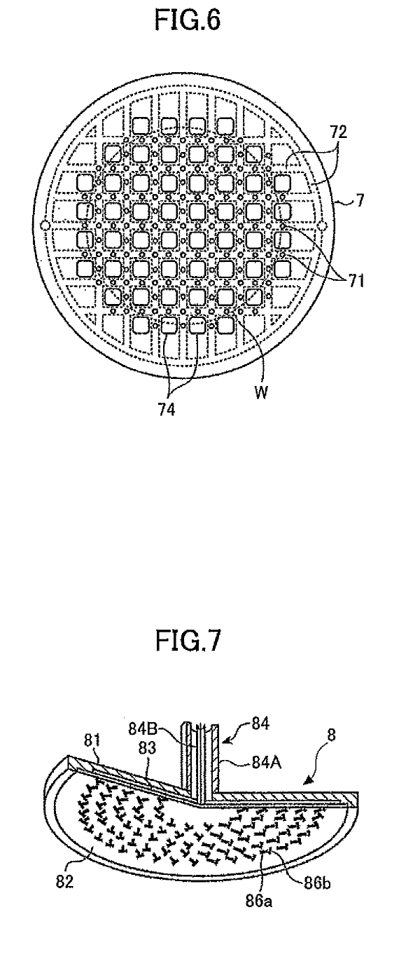

In addition, the chamber 5 is provided with a second gas-supplying portion 7 having, for example, a substantially circular top view shape. The second gas-supplying portion 7 is located between the susceptor 51 and the first gas-supplying portion 6 so that the susceptor 51 and the first gas-supplying portion 6 are separated. The second gas-supplying portion 7 is formed of an electrically conductive material such as, for example, a magnesium (Mg) containing aluminum compound, an aluminum added stainless steel and the like. Referring to FIG. 6, the second gas-supplying portion 7 includes a lattice-shaped gas passage 72 that is in communication with one end portion of plural second gas-supplying orifices 71 that are open toward the susceptor 51. The gas passage 72 is connected to one end portion of the second gas-supplying conduit 73 (FIG. 5). Additionally, plural openings 74 are formed in the second gas-supplying portion 7 in order to penetrate the second gas-supplying portion 7. The openings 74 are located between adjacent gas passages 72 in order to allow the plasma and the source gases in the plasma to pass through toward a space below the second gas-supplying portion 7.

As shown in FIG. 5, the second gas-supplying portion 7 is connected to a supplying source 75 of the nitrogen gas as a source gas and a supplying source 76 of the trimethylsilane (3 MS) as a source gas, when the barrier film 13 is deposited, for example. The nitrogen gas and the trimethylsilane flow to the second gas passage 72 through the second gas-supplying conduit 73 and are uniformly supplied to the space below the second gas supplying-portion 7 through the gas-supplying orifices 71. In this illustrated example, the supplying sources 75, 76, the second gas-supplying conduit 73, and the second gas-supplying portion 7 constitute a gas supplier that supplies the source gases to the chamber 5. In FIG. 5, V1, V2, and V3 denote valves and 101, 102, and 103 denote flow rate controllers that control flow rates of the argon gas, the nitrogen gas, and trimethylsilane gas, respectively, which are supplied to the chamber 5. When the CF film 10 (20) is deposited, the supplying source 76 may be a container (or vaporizer) filled with the C₅F₈ gas, from which the C₅F₈ gas is uniformly supplied to the space below the second gas-supplying conduit 73.

Referring to FIG. 5, a cover plate 53 formed of a dielectric material such as aluminum oxide is provided on the first gas-supplying portion 6 via a seal member (not shown) such as an O-ring. An antenna portion 8 is provided to closely fit on the cover plate 53. As shown in FIG. 7, the antenna portion 8 includes an antenna body 81 having a circular top view shape and a planar antenna member (slot plate) 82 having a disk shape. The antenna body 81 has a stepped concave portion directed to the cover plate 53. The planar antenna member 82 has plural slots and is arranged to close the concave portion of the antenna body 81 so that a hollow space remains between the antenna body 81 and the planar antenna member 82. The antenna body 81 and the planar antenna member 82 are made of an electrically conductive material and constitute a flat disk-shaped waveguide. As shown in FIG. 5, the antenna portion 8 is placed on the chamber 5 so that the lower surface of the planar antenna member 82 contacts the cover plate 53.

A phase-retarding plate 83 formed of a low-loss dielectric material such as aluminum oxide, silicon nitride (Si₃N₄) and the like is provided between the planar antenna member 82 and the antenna body 81. In other words, the phase-retarding plate 83 occupies the hollow space between the antenna body 81 and the planar antenna member 82. The phase-retarding plate 83 shortens the wavelength of microwaves propagating in the circular waveguide (antenna portion 82. The antenna body 81, the planar antenna member 82, and the phase-retarding plate 83 constitute a Radial Line Slot Antenna, in this embodiment.

The antenna portion 8 so configured is attached on the chamber 5 via a seal member (not shown) so that the planar antenna member 82 closely contacts the cover plate 53. The antenna portion 8 is connected to a microwave generator 85, which is provided outside of the chamber 5, via a coaxial waveguide 84. With this, microwaves having a frequency of, for example, 2.45 GHz or 8.3 GHz are supplied to the antenna portion 8. Specifically, an outer waveguide pipe 84A, which is an outer portion of the coaxial waveguide 84, is connected to the antenna body 81, and a center conductor 84B is connected to the planar antenna member 82 through an opening formed in the phase-retarding plate 83.

The planar antenna member 82 is formed of a copper plate having a thickness of, for example, 1 mm and includes plural slots 86 for generating, for example, circular polarized waves, as shown in FIG. 7. Each of the slots 86 has a pair of a slot 86a and a slot 86b that are arranged into a T-shape with a slight distance between the slot 86a and the slot 86b. The slot pairs of the slots 86a and 86b are distributed concentrically or spirally in the planar antenna member 82. Because the slots 86a and 86b are arranged to be substantially orthogonal to each other, circular polarized waves having two polarization components orthogonal to each other are radiated from the slots 86. The slots 86 are arranged at intervals corresponding to the wavelength of the microwaves, which is shortened by the phase-retarding plate 83, and thus substantially planar microwaves are radiated from the planar antenna member 82 to the inside of the chamber 5. In this embodiment, the microwave generator 85, the coaxial waveguide 84, and the antenna portion 8 constitute a plasma generator.

Referring to FIG. 5, exhaust pipes 54 are connected to a bottom portion of the chamber 5 and linked into a junction pipe that in turn is connected to a vacuum pump 56, so that the chamber 5 can be evacuated to a predetermined reduced pressure under control of a pressure control unit 55 provided in the junction pipe.

In the plasma enhanced deposition apparatus, the microwave generator 85, the high frequency electric power source 82, the valves V1, V2, and V3 for supplying the plasma gas and the source gases, the flow rate controllers 101, 102, and 103, the pressure control unit 55, and the like are controlled by a control unit 200 including a computer in accordance with a computer program incorporating steps in order to carry out the deposition of each film explained above at predetermined conditions. The program is stored in a computer readable medium such as a flexible disk, a compact disk, a flash memory, a magneto optical disk (MO) and the like, and installed in the control unit 200.

Next, an example of a deposition method carried out in order to deposit the barrier film 13 by the plasma enhanced deposition apparatus is explained. First, the wafer W is transferred into the chamber 5 through the gate valve (not shown) and placed on the susceptor 51. The wafer W has the lower level interconnection layer formed in preceding process steps on the surface. Then, the chamber 5 is evacuated to a predetermined reduced pressure and the plasma gas (e.g., argon gas), which is to be excited in plasma by the microwaves, is supplied to the first gas supplying portion 6 through the first gas-supplying conduit 63 at a predetermined flow rate of, for example, 1000 sccm. The nitrogen gas and the trimethylsilane gas, which are the source gases, are supplied to the second gas-supplying portion 7, which serves as a source gas-supplying portion, through the second gas-supplying conduit 73 at predetermined flow rates of, for example, 50 sccm and 40 sccm, respectively. The inner pressure of the chamber 5 is maintained at a process pressure of, for example, 17.3 Pa (130 mTorr), and the susceptor 51 is heated to and maintained at, for example, 380° C.

Next, the high frequency waves (microwaves) having a frequency of 2.45 GHz are supplied with electric power of 2500 watts from the microwave generator 85. The microwaves propagate in a Transverse Magnetic (TM), Transverse Electric (TE), or Transverse Electromagnetic (TEM) mode inside the coaxial waveguide 84 to the planar antenna member 82 of the antenna portion 8. Then, while radially spreading in the planar antenna member 82 from the center to the circumference of the planar antenna member 82, the microwaves are radiated from the slot pairs 86a, 86b toward a process space below the first gas supplying portion 6 through the cover plate 53 and the first gas-supplying portion 6.

Because the cover plate 53 and the first gas-supplying portion 6 are made of a material, for example, aluminum oxide, which allows the microwaves to pass through, in order to serve as a microwave window, the microwaves effectively pass through the cover plate 53 and the first gas-supplying portion 6. In addition, because the slot pairs 86a, 86b are arranged in the above-mentioned manner, the circular polarized waves are uniformly radiated from the entire area of the planar antenna member 82, and thus an electric field density becomes uniform in the process space below the planar antenna member 82. Therefore, uniform high density plasma is generated in the entire process space below the planar antenna member 82 by the microwave energy. The plasma flows toward the process space below the second gas-supplying portion 7 through the openings 74 of the second gas supplying portion 7, and activates the source gases supplied from the second gas supplying portion 7 to the process space to produce the active species, which in turn are transported to the upper surface of the wafer W. At this time, high frequency electric power of, for example, 10 watts is applied from the high frequency electric power source 52 to the susceptor 51, which affects the active species being transported toward the wafer W. In such a manner, the barrier film 13 composed of SiCN is deposited through the active species on the wafer W.

After the barrier film 13 is deposited, the plasma gas and the source gases are stopped and the chamber 5 is evacuated to vacuum. Then, the source gases are switched from the nitrogen gas and the trimethylsilane to the C₅F₈ gas. The C₅F₈ gas and the plasma gas are supplied to the chamber 5; the inside of the chamber 5 is maintained at a predetermined reduced pressure; and high frequency electric power having a wavelength of, for example, 2.45 GHz is supplied at a predetermined power level of, for example, 2750 watts from the microwave generator 85, so that the CF film 20 is deposited. Then, the wafer W having the CF film 20 deposited on the top is transferred out from the chamber 5 through the gate valve (not shown). The series of the procedures from the transfer-in of the wafer W to the chamber 5 through the transfer-out of the wafer W from the chamber 5 are carried out under control of the control unit 200 that has read out the program from the computer readable medium 201.

In this embodiment, when the argon gas, the nitrogen gas, and the trimethylsilane are excited into plasma by which the barrier film 13 formed of SiCN is deposited on the lower level circuit layer of the wafer W, the high frequency bias electric power is supplied to the wafer W thought the susceptor 51. Therefore, the argon ions in the plasma are drawn toward the wafer W and collide against the active species of the trimethylsilane gas and the upper surface of the wafer W. As a result, the barrier film 13 becomes dense, thereby improving the barrier capability of the barrier film 13. The presumed principle of the improved barrier capability is as explained above. Due to the improvement, when the multilayer interconnect structure configured in the above manner is annealed at a temperature of, for example, 400° C., diffusion of copper atoms in the interconnect metal 11 into the CF film 20 (FIG. 3C) as the interlayer insulating film at the upper level is prevented or impeded. In addition, diffusion of fluorine atoms, which may be outgas components from the CF film 20, into the interconnect metal 11 is also prevented or impeded.

Therefore, even when the barrier film 13 needs to be thinner, an increase in leakage current, which may be caused by the metal diffusion into the interlayer insulating film, and an increase in resistivity of the interconnect metal 11, which may be caused by the fluorine diffusion into the interconnect metal 11, can be prevented or impeded. Therefore, this embodiment of the present invention is advantageous for further miniaturization and high-level integration of the semiconductor device. This embodiment of the present invention is also advantageous in that the interlayer insulating film is realized with the CF film that has been thought disadvantageous in terms of fluorine outgas when heated but advantageous due to a low relative dielectric constant.

The interlayer insulating film employed in the semiconductor device fabricated through the deposition method according to the embodiment of the present invention is not limited to the CF film but may be formed of SiCO, SiCOH, SiOF, silicon oxide, and the like.

Regarding the magnitude of the bias power of the high frequency waves applied to the wafer W during the deposition of the barrier film 13, it is thought from experiments described later that the barrier capability of the barrier film 13 is further improved as the bias power is increased. However, because visible failures are observed at the bias power of 20 watts, the bias power is preferably 15 watts or less. In other words, the bias power per unit area of the wafer W is preferably 0.048 watts/cm² or less (the wafer surface area of the wafer W having a diameter of 200 mm is about 314.16 cm²).

The barrier film 13 may be a SiC film rather than the SiCN film. The SiC film can be deposited by, for example, supplying the trimethylsilane gas as the source gas without the nitrogen gas.

In addition, the barrier film 13 may be an amorphous carbon film, which can be deposited by using 2-butyne gas (C₄H₆) as the source gas. In this case, while 2-butyne gas is preferable, 1-butyne gas, ethylene gas, acethylene gas and the like may be used. Additionally, the barrier film 13 may be a silicon-added amorphous carbon film, which can be deposited by using a carbon hydride gas, an example of which is mentioned above, and a gas including silicon, for example, a silane series gas in addition to the carbon hydride gas. In this case, the silane series gas may include monosilane gas, disilane gas, trimethylsilane, and the like.

Moreover, while the planar antenna type plasma enhanced deposition apparatus is used in order to supply microwaves in this embodiment, a parallel plate type plasma enhanced deposition apparatus may be used in other embodiments.

### EXAMPLES

### Experiment 1: Comparison Test of an Outgas Amount at Elevated Temperatures

In this experiment, a wafer having a diameter of 200 mm (8 inches) was used. First, the plasma enhanced plasma deposition apparatus was used to deposit the CF film on the wafers and the SiCN film having a thickness of 30 nm on top of the CF film. Deposition conditions were as mentioned above. However, the bias power at the time of depositing the SiCN film was set as follows.

### (Bias Power)

Working Example 1: 30 watts
Comparison Example 1: 0 watts

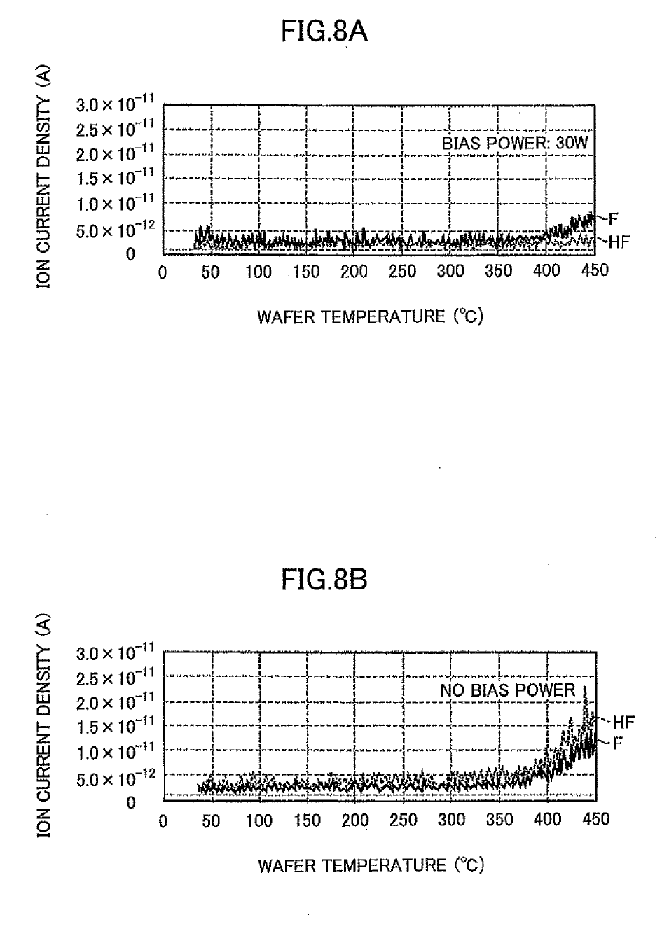

The two wafers were heated and an amount of the outgas (HF, F) from each wafer was measured in accordance with a thermal desorption method. The measurement results are shown in FIGS. 8A and 8B. In each wafer, the amount of the outgas from the wafer increases with an increase in temperature. However, the amount of HF and F outgassing from the wafer is less in the case of Working Example 1, where the SiCN film has been deposited with the bias power applied to the wafer W, compared to the wafer of Comparison Example 1. The HF and F are thought to outgas from the CF film, which is the underlying film of the SiCN film, through the SiCN film. This indicates that the SiCN film deposited with the bias power has a higher barrier capability against the constituent components of the underlying layer.

### Experiment 2: Comparison Test of Interfusion of Elements Along a Thickness Direction

In the experiment 2, the same multilayer structures were prepared with three different bias power conditions during the SiCN film deposition, as follows.

### (Bias Power)

Working Example 2-1: 5 watts
Working Example 2-2: 10 watts
Comparison Example 2: 0 watts

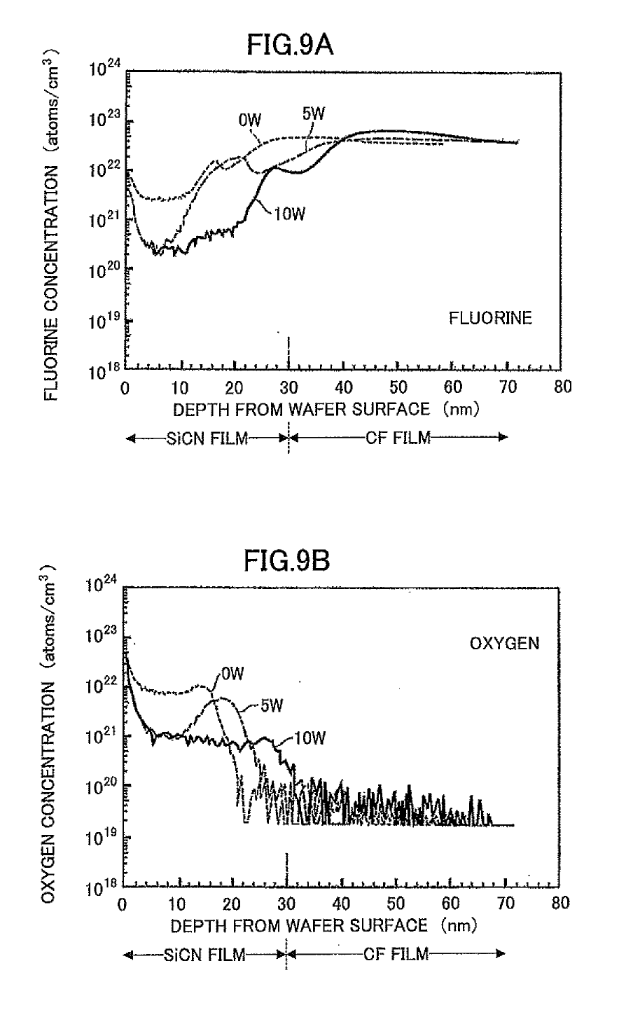

The three wafers underwent an annealing at about 400° C. for about 60 minutes. Then, secondary ion mass spectrometry (SIMS) was carried out for each of the three wafers in order to obtain an element profile of fluorine and oxygen atoms along the depth direction from the wafer surface. The experimental results are shown in FIG. 9. It is understood from FIG. 9 that while the fluorine and oxygen atoms are contained in the SiCN film in every wafer, the amount of these atoms is decreased in the order of Comparison Example 2, Working Example 2-1, and Working Example 2-2. The fluorine atoms contained in the SiCN film are thought to originate from the following two sources. One is the CF film that underlies the SiCN film. Namely, the fluorine atoms diffuse into the SiCN film from the CF film during the deposition and annealing. The other is the chamber wall of the deposition apparatus. Namely, the fluorine atoms, which once are adsorbed on the wall of the deposition chamber during the deposition of the CF film, are desorbed from the wall and incorporated into the SiCN film during the deposition of the SiCN film. Therefore, the higher bias power is effective to improve the barrier capability of the SiCN film against the fluorine atoms from the CF film even when the SiCN film is deposited and annealed. In addition, the higher bias power is also effective to reduce the amount of the fluorine atoms from the deposition environment during the deposition of the SiCN film.

On the other hand, the oxygen in the SiCN film is thought to be incorporated from the inner wall of the chamber 5 during the deposition of the SiCN film. The higher bias power is more effective to reduce the amount of the oxygen atoms from the deposition environment during the deposition of the SiCN film.

The reason why the barrier capability against the fluorine atoms from the CF film is improved when the higher bias power is applied is considered to be that the SiCN film can become dense due to the bombardment of the argon ions, as explained above. In addition, the reason why the amounts of the fluorine and the oxygen atoms from the chamber environment are reduced during the deposition of the SiCN film is considered to be that the argon ions may expel these atoms in the chamber 5.

### Experiment 3: Deposition Rate and Refractive Index

In the experiment 3, the same multilayer structures were prepared with three different bias power conditions during the SiCN film deposition, while a deposition time of the SiCN film is kept constant for the three wafers.

### (Bias Power)

Working Example 3-1: 5 watts
Working Example 3-2: 10 watts
Comparison Example 2: 0 watts

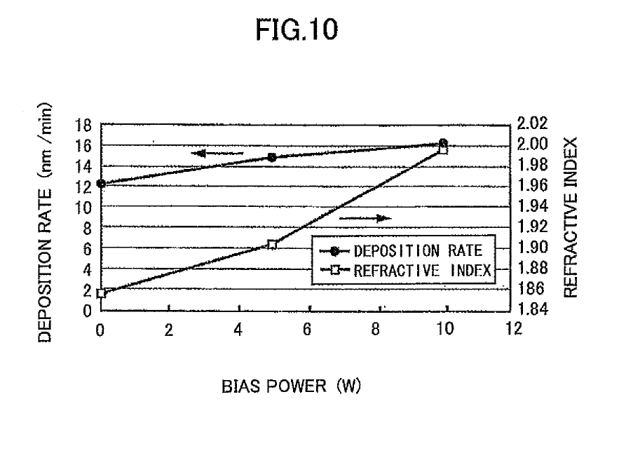

The deposition rates of the SiCN films were calculated from the corresponding thicknesses of the SiCN films deposited on the wafers. In addition, the refractive indexes of the SiCN films were measured. As shown in FIG. 10, the deposition rate and the refractive index are increased when the higher bias power is increased. As explained above, the argon ion bombardment onto the SiCN film may produce dangling bonds on the surface of the SiCN film, which increases the sticking coefficient of the active species on the surface, thereby increasing the deposition rate. In addition, from a relationship where the refractive index increases or decreases along with the film density, it can be presumed that the increased refractive index results in the increased film density.

### Experiment 4: Appearance and Adhesiveness

While it has been understood from the above experiments that the higher bias power realizes the higher barrier capability of the SiCN film, the experiment 4 was carried out in order to investigate whether the higher bias power brings about any adverse effect on the other characteristics of the SiCN film. Specifically, an appearance test and an adhesion test were carried out for the wafers having the same multilayer structure as Experiment 1. More specifically, the appearance test was carried out by observing a cross section of the multilayer structure using Secondary Electron Microscopy (SEM). In addition, the adhesion test on the SiCN film was carried out by a tape test. Namely, after grooves in the shape of a square having sides of about 5 mm were made in the surface of the wafer by using a diamond cutter, an adhesive tape was affixed on the entire surface of the wafer, and the adhesive tape was peeled off from the wafer. The wafers with the multilayer structure were prepared in substantially the same manner as Experiment 1 while process conditions during the deposition of the SiCN film, which include the deposition temperature and the bias power, were changed wafer by wafer as follows,

### (Process Conditions)

Deposition temperature (° C.): 150, 200, 250, 300, 340, 380, 420
Bias Power (watt): 0, 5, 10, 15, 20

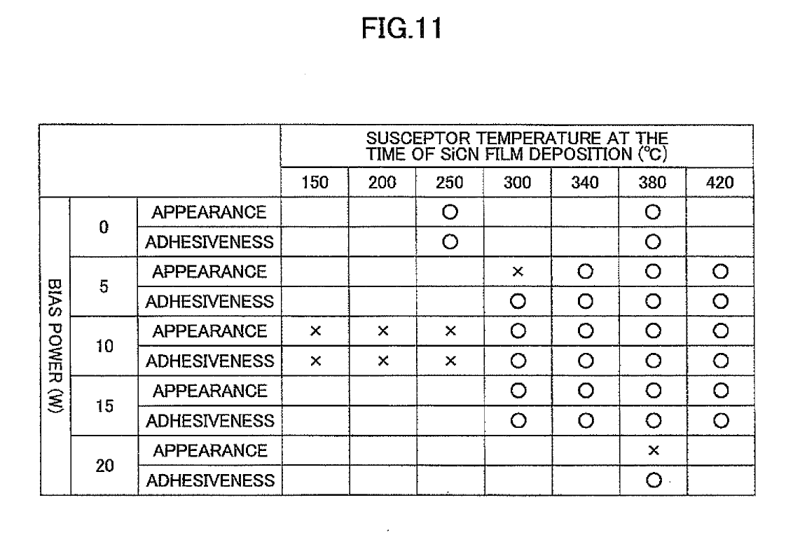

The experimental results are summarized in FIG. 11, which shows that the appearance and the adhesiveness of the SiCN film are deteriorated as the deposition temperature of the SiCN film decreases. In addition, when the bias power is 20 watts or more, voids were created at the cross section of the multilayer structure. From these results, it has been found that the bias power during the deposition of the SiCN film is preferably 15 watts or less, namely 0.048 watts/cm² or less, which is obtained by dividing 15 watts by the entire surface area (314.16 cm²) of the wafer having the diameter of 200 mm. In addition, it has been found that the deposition temperature during the deposition of the SiCN film is preferably 340° C. or more.

Experiment 5: Test #1 on Adhesion Strength of SiCN film Onto CF Film

In this experiment, the wafers with the multilayer structure were prepared in substantially the same manner while the bias power was varied wafer by wafer as follows.

### (Bias Power)

Working Example 5: 30 watts
Comparison Example 5: 0 watts

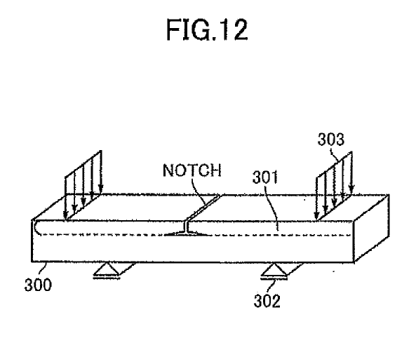

A strength test called a four point bending method was carried out for the wafers in order to investigate the adhesion strength between the SiCN film and the CF film in the following manner. As shown in FIG. 12, a wafer 300 having the above multilayer structure was adhered on a bare wafer 301 by an epoxy resin, and a notch was made on the bare wafer 301 side in order to prepare a test sample. Then, this sample was placed on two supporting rods 302 arranged in parallel, and the sample was pressed down by two pressing rods 303, each of which was located outside of the corresponding one of the two supporting rods 302. Whether a boundary face was fractured was determined in accordance with a transition in displacement along the thickness direction. For details about the four point bending method, see the Journal of Applied Mechanics, MARCH 1989, vol. 56, pp. 77-82.

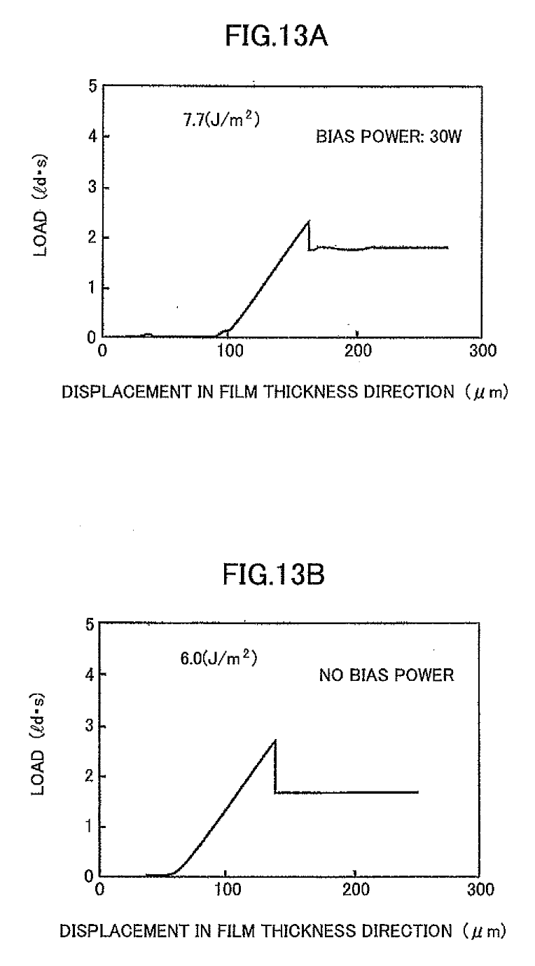

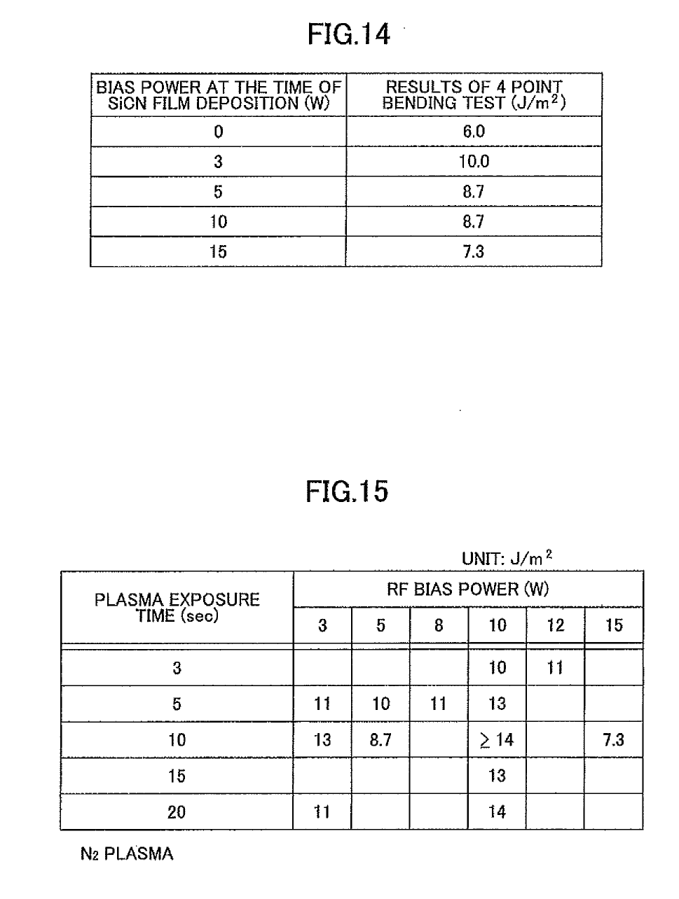

The method was carried out seven times for each wafer, and the average load that causes fracture was obtained as shown in FIGS. 13A and 13B. From the results, the load at the time of fracture is 7.7 J/m² in the case of Working Example 5, and 6.0 J/m² in the case of Comparison Example 5. Therefore, it is found out that application of the bias power during the SiCN film deposition can increase the adhesion strength of the SiCN film onto the CF film.

### Experiment 6: Test #2 on Adhesion Strength of SiCN Film Onto CF Film

In Experiment 6, effects of the bias power were further investigated, specifically in a range of 15 watts or less, which was found to be preferable from Experiments 4 and 5. The multilayer structures were prepared in substantially the same manner while the bias power was changed wafer by wafer as follows.

### (Bias Power)

Working Example 6: 3, 5, 10, 15 watts
Comparison Example 6: 0 watts

The four point bending method was carried out for these wafers in order to measure the adhesion strength of the SiCN film onto the CF film. As a result, application of the bias power turned out to be effective in the entire range from about 3 through about 15 watts (about 0.0095 through about 0.047 watts/cm²)

### Experiment 7: Test #3 on Adhesion Strength of SiCN Film Onto CF Film

The adhesion strength between the SiCN film as the barrier film and the underlying CF film is very important to fabricate a semiconductor device including a copper interconnection multilayer structure, in a sense. From this point of view, the present invention is directed to a technique for property modification of the surface of the CF film in order to improve the adhesion strength. Specifically, after the CF film is deposited, the surface of the CF film is exposed to nitrogen plasma and/or noble gas plasma such as argon plasma while applying the bias power to the wafer on which the CF film is deposited. During this exposure of the plasma, the nitrogen ions and/or the argon ions impinge upon the surface of the CF film. This is referred to as a bias plasma process below. The inventors of the present invention believe that, due to this bias plasma process, the surface property of the CF film is modified, or fluorine atoms in the superficial layer of the CF film are desorbed by the ions, so that the superficial layer becomes carbon-rich. As a result, even when heated, for example, during a subsequent film deposition, an annealing process and the like, the amount of outgas from the CF film can be reduced. In addition, because of the fluorine adsorption, the surface of the CF film may be moderately roughened, thereby providing an anchor effect for the overlying film, according to the inventors' thoughts.

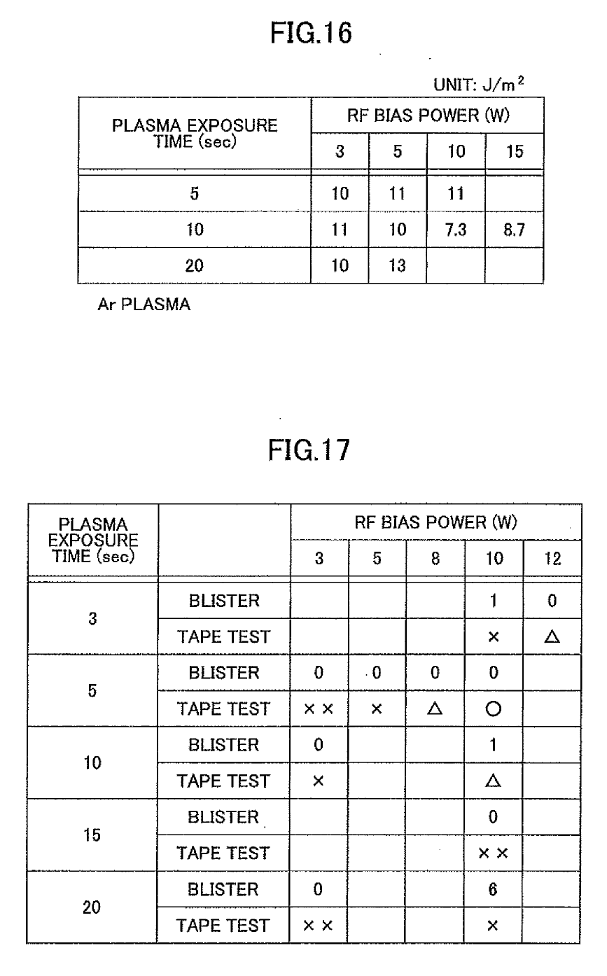

Moreover, the inventors of the present invention also believe that because the surface of the CF film is bombarded with the ions, dangling bonds are formed, and the dangling bonds are bonded with precursors for the SiCN film that is deposited on the CF film, which increases the adhesion strength. According to such thought, Experiment 7 was carried out, in which the CF films were deposited in the above manner, the bias plasma process was carried out for the CF films with various combinations of the bias power and the plasma exposure time as listed in FIGS. 15 and 16, and the SiCN films were deposited on the CF films without the bias power. Then, the adhesion strength between the CF film and the SiCN film was evaluated by the four point bending method. FIG. 15 summarizes the results of the bias plasma process using the nitrogen gas, and FIG. 16 summarizes the results of the bias plasma process using the argon gas. In FIGS. 15 and 16, the values greater than or equal to 10 are rounded to the nearest whole number.

According to the experimental results, while the higher values are seemingly obtained when the bias plasma process using the nitrogen gas is carried out, the difference between the nitrogen gas and the argon gas is not significant. However, all the values listed in FIGS. 15 and 16 exceed 6.0 J/m² that is obtained for Comparison Example 4 that corresponds to a conventional technique. Especially, the values two times greater than the conventional value are obtained in the bias plasma process using either one of the nitrogen gas and the argon gas, while the value slightly decreases when the bias power comes close to 15 watts.

From the above discussion, the bias power during the bias plasma process carried out for the CF film is preferably about 3 through about 15 watts (about 0.0095 through about 0.047 watts/cm²). Although data are not listed in FIGS. 15 and 16, an adhesion strength of about 11.3 J/m² was obtained when the CF film underwent the bias plasma process and the SiCN film was deposited on the CF film by applying the bias power during the deposition of the SiCN film. This result suggests that the adhesion strength between the CF film and the SiCN film can be increased regardless of the deposition method of the SiCN film when the bias plasma process is carried out for the CF film.

Next, results of a more severe experiment are explained. In this experiment, the SiCN film was deposited without the bias power on the CF film that underwent the bias plasma process, and then a silicon oxide film was deposited on the SiCN film to obtain a multilayer structure. Then, the wafer with the multilayer structure was annealed at a temperature of about 400° C. for about 60 minutes. After this, a surface observation and the tape test were carried out. The surface observation was carried out by counting the number of blisters (air bubbles), which are signatures of outgassing from the CF film. The tape test was the same as explained above. The experimental results are shown in FIG. 17.

Regarding the tape test results shown in FIG. 17, open circles show that no squares of the film(s) having sides of 5 mm are peeled off; open triangles show that the film(s) is peeled off from about half the wafer surface; double crosses show that the film(s) is peeled off from the entire wafer surface; single crosses show that the film(s) is peeled off from about half to all the wafer surface. Because this test imposes a severe burden on the wafers, which exceeds a thermal budget (thermal history) that the wafer goes through when a semiconductor device is fabricated, the open circles and the open triangles are thought to be acceptable. According to this standard, the bias power during the bias plasma process carried out for the CF film is preferably about 3 through about 15 watts and more preferably about 8 through about 12 watts (about 0.025 through about 0.038 watts/cm²). By applying the bias power as low as 15 watts to the wafer in order to modify the surface of the CF film, the adhesion strength of the SiCN film on the CF film can be increased through the fluorine desorption from the superficial layer of the CF film without damaging the CF film.

The present application is based on Japanese Patent Application No. 2007-256330, filed on Sep. 28, 2007 with the Japanese Patent Office, the entire content of which is hereby incorporated herein by reference.

What is claimed is:

1. A deposition method of depositing a barrier film to be interposed between an interconnect metal and an interlayer insulating film, the method comprising steps of:
placing a substrate on a susceptor in a process chamber;
supplying to the process chanter a source gas including an organic compound and a plasma gas for facilitating activation of the source gas into plasma;
evacuating the process chamber to a reduced pressure;
generating plasma of the plasma gas and the source gas in the process chamber to deposit the barrier film including carbon on the substrate; and
applying high frequency bias electric power to the susceptor during the plasma generating step.

2. The deposition method of claim 1, wherein the plasma gas and the source gas are supplied to the process chamber from different supplying ports and activated into plasma by supplying microwaves to the process chamber through a planar antenna member including plural slots formed along a circumferential direction, the planar antenna member being arranged in an upper portion of the process chamber in order to face the susceptor.

3. The deposition method of claim 2, wherein the high frequency bias electric power per unit area of the substrate is 0.047 watts/cm² or less.

4. The deposition method of claim 1, wherein the source gas includes a silicon organic compound, and wherein the barrier film includes silicon.

5. The deposition method of claim 4, wherein the barrier film is a SiCN film.

6. The deposition method of claim 4, wherein the barrier film is a SiC film.

7. The deposition method of claim 1, wherein the barrier film is an amorphous carbon film.

8. The deposition method of claim 7, wherein the source gas is butyne gas.

9. The deposition method of claim 8, wherein the source gas includes a silane series gas in addition to the butyne gas, and wherein the amorphous carbon film includes silicon.

10. The deposition method of claim 1, wherein the plasma gas is argon gas.

11. The deposition method of claim 1, wherein the interlayer insulating film is a fluorine-added carbon film.

12. A deposition apparatus by which a barrier film to be interposed between an interconnect metal and an interlayer insulating film is deposited, the apparatus comprising:
a process chamber including a susceptor on which a substrate is placed;
a gas supplying portion that supplies to the process chamber a source gas including an organic compound and a plasma gas for facilitating activation of the source gas into plasma;
an evacuation unit that evacuates the process chamber to a reduced pressure;
a plasma generation portion that activates the gas in the process chamber into plasma;
an applying unit that applies high frequency bias electric power to the susceptor; and
a control unit that controls the gas supplying chamber, the gas supplying portion, the evacuation unit, the plasma generation portion and the applying unit so that the plasma gas and the source gas including the organic compound are supplied to the process chamber and activated into plasma and the barrier film including carbon is deposited with the high frequency bias electric power applied to the susceptor.

13. The deposition apparatus of claim 12, wherein the gas supplying portion includes a supplying port through which the plasma gas to be excited by microwaves is supplied to the process chamber and another supplying port through which the source gas is supplied to the process chamber; and
wherein the plasma generation portion includes a waveguide that guides the microwaves to an upper portion of the process chamber, and a planar antenna member that is connected to the waveguide in order to guide the microwaves from the waveguide to the process chamber and arranged to face the susceptor, the planar antenna member including plural slots formed along a circumferential direction.

14. The deposition apparatus of claim 13, wherein the high frequency bias electric power per unit area of the substrate is 0.047 watts/cm² or less.

15. A computer readable medium including a computer program stored therein, wherein the computer program is executed on a computer in a deposition apparatus, and wherein steps of performing the deposition method of claim 1 are incorporated in the computer program.

16. A semiconductor device comprising a barrier film deposited by the deposition method of claim 1.
